(19) United States
(12) Patent Application Publication
(10) Pub. No.: US 2013/0034966 A1
(43) Pub. Date: Feb. 7, 2013

(54) CHEMICAL DISPERSION METHOD AND DEVICE

(71) Applicants: Ming-Hsi Yeh, Hsinchun (TW); Kuo-Sheng Chuang, Hsinchu City (TW); Ying-Hsueh Chang Chien, New Taipei City (TW); Chi-Ming Yang, Hsian-San District (TW); Chi-Wen Liu, Hsinchu (TW); Chin-Hsiang Lin, Hsin-Chu (TW)

(72) Inventors: Ming-Hsi Yeh, Hsinchun (TW); Kuo-Sheng Chuang, Hsinchu City (TW); Ying-Hsueh Chang Chien, New Taipei City (TW); Chi-Ming Yang, Hsian-San District (TW); Chi-Wen Liu, Hsinchu (TW); Chin-Hsiang Lin, Hsin-Chu (TW)

(73) Assignee: Taiwan Semiconductor Manufacturing Company, Ltd., ("TSMC"), Hsin-Chu (TW)

(21) Appl. No.: 13/198,420

(22) Filed: Aug. 4, 2011

(51) Int. Cl. H01L 21/306; B05B 1/00

(52) U.S. Cl. 438/704; 222/566; 257/E21.219

(57) ABSTRACT

A method of semiconductor fabrication including providing a semiconductor wafer and dispensing a first chemical spray onto the wafer using a first nozzle and dispensing a second chemical spray using a second nozzle onto the wafer. These dispensing may be performed simultaneously. The method may further include moving the first and second nozzle. The first and second nozzle may provide the first and second chemical spray having at least one different property. For example, different chemical compositions, concentrations, temperatures, angles of dispensing, or flow rate. A chemical dispersion apparatus providing two nozzles which are operable to be separately controlled is also provided.

### BACKGROUND

Embodiments of this disclosure relate generally to semiconductor fabrication, and more particularly to a method and apparatus for applying a chemical to a semiconductor wafer.

As the technology of semiconductor fabrication progresses, the substrates (e.g., wafers) upon which the semiconductor devices are formed are increasing in size. For example, fabrication processes are currently targeting 450 mm wafers. As the wafer size increases and device dimensions decrease, within wafer uniformity becomes both more critical and more difficult to control. One tool in which maintaining wafer uniformity have been a challenge to the semiconductor industry is the single-wafer cleaning or wet etching tool. The conventional tools may impact the uniformity as chemical is delivered to the wafer at a single location. This can lead to chemical decay as the chemical travels across the wafer or cooling down of the chemical as it travels across the wafer. These can negatively impact the etching rate of the chemical and thus, create non-uniformity.

Presently considered methods for improving uniformity include increasing a rotational speed of the target wafer and moving the nozzle used for dispersion across the wafer. Both of these methods have drawbacks. For example, increasing the speed of the wafer rotation can cause pattern damage and contamination of the processing chamber. Similarly, moving the nozzle across the wafer can cause contamination of the processing chamber and/or have a negative impact on the cleaning performance. Thus, what is needed is a method and apparatus for dispersing chemicals, such as used in cleaning or etching processes, onto a wafer.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1a and 1b illustrate an embodiment of an apparatus for dispersing chemicals onto a semiconductor substrate according to one or more aspects of the present disclosure.

FIG. 2 is an embodiment of an apparatus having more and two nozzles for dispersing chemicals onto a semiconductor substrate according to one or more aspects of the present disclosure.

FIG. 3 is an embodiment of an apparatus for dispersing chemicals onto a semiconductor substrate having according to one or more aspects of the present disclosure and illustrating a scan mode.

FIG. 4 is an embodiment of one configuration of an apparatus for dispersing chemicals onto a semiconductor substrate according to one or more aspects of the present disclosure.

FIG. 5 is an embodiment of a second configuration of an apparatus for dispersing chemicals onto a semiconductor substrate according to one or more aspects of the present disclosure.

FIG. 6 is a schematic of a block diagram of a control system associated with an apparatus for dispersing chemicals onto a semiconductor substrate according to one or more aspects of the present disclosure.

FIG. 7 is a flowchart of an embodiment of a method of dispersing chemicals onto a semiconductor device according to various aspects of the present disclosure in another embodiment.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

The present disclosure is directed, at times, to integrated circuit device or semiconductor device manufacturing. However, one would recognize the benefits of the present disclosure can be applied in other device technologies, such as liquid crystal display (LCD) and/or any other technology which require similar dispersion of chemicals onto a substrate. The term chemical as used herein includes any liquid or gaseous substance including water, pure chemicals, mixtures, and the like.

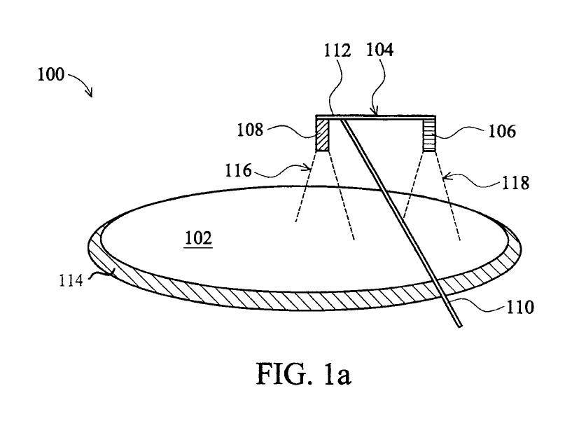

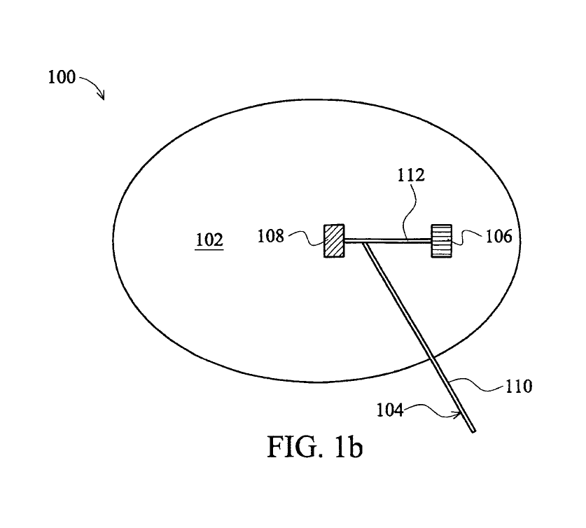

FIG. 1a is a perspective view of an embodiment of a chemical dispersion apparatus 100. The chemical dispersion apparatus 100 is a single-wafer tool (i.e., one wafer is processed at a time). The chemical dispersion apparatus 100 includes an arm device 104, a first nozzle 106, a second nozzle 108, and a chuck 114 provided in a chamber. A single wafer 102 is placed on the chuck 114. The arm device 104 includes a main arm 110 and a nozzle positioning arm 112. The chemical dispersion apparatus 100 provides a chemical 116 and a chemical 118 to the wafer 102. The chemical 116 is dispersed from the second nozzle 108; the chemical 118 is dispersed from the first nozzle 106. FIG. 1b illustrates a corresponding top view.

The wafer 102 may have one or more layers (e.g., insulating layers, conductive layers, etc) formed thereon. The wafer 102 may include silicon. Alternatively, the wafer 102 includes germanium, silicon germanium or other proper semiconductor materials. In one embodiment, the wafer 102 includes regions where one or more semiconductor devices are formed (e.g., field effect transistors). Various isolation features may be formed in the wafer 102. The wafer 102 also includes various doped regions (e.g., n-wells and p-wells) formed in various active regions. The wafer 102 includes a plurality of individual die formed thereon, which may be subsequently diced to form semiconductor devices. In an embodiment, the wafer 102 is 450 mm in diameter.

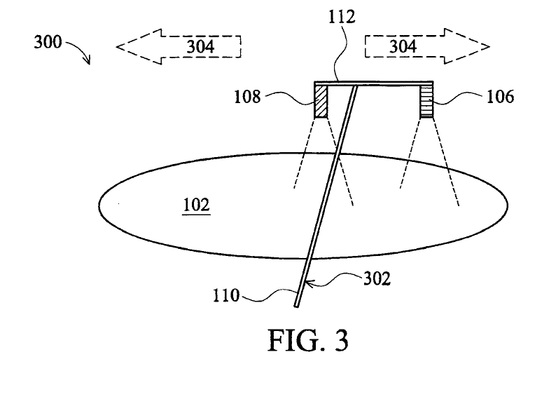

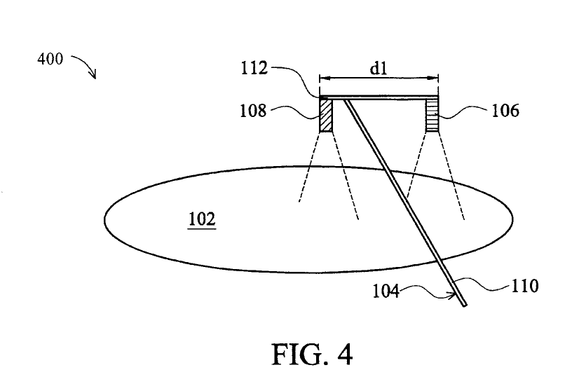

The wafer 102 is disposed on the chuck 114. The wafer 102 may be positioned with a top surface having semiconductor devices (or portions thereof) formed thereon. The chuck 114 may be operable to provide an angular velocity to the wafer 102 (i.e., rotate the wafer 102). The wafer 102 may be at room temperature. The arm device 104 includes the main arm 110 and nozzle positioning arm 112 and is operable to hold and/or move the nozzles 106 and 108. In an embodiment, the main arm 110 and/or the nozzle positioning arm 112 includes a chemical delivery system operable to deliver chemicals to or from the nozzles 106 and 108. In an embodiment, the chemical delivery system includes a bundle of tubes or piping to deliver the chemical(s). The arm device 104 may further include functionality to alter the angle of the nozzles 106 and/or 108, to alter the temperature of the chemical delivered to the nozzle 106 and/or 108, to alter the chemical type delivered from the chemical delivery system, to alter the chemical concentration delivered from the chemical delivery system, to alter the flow rate of the chemical delivered to and/or by the nozzles 106 and/or 108, and/or to alter the physical location of the nozzles 106 and/or 108. The arm 104 may be operably coupled to a controller, which can determine and/or control the chemical composition delivered, the chemical concentration delivered, the temperature of chemical, the angle of the nozzles 106 and/or 108, the physical location of the nozzles 106 and/or 108, the flow rate of chemical to or provided by the nozzles 106 and/or 108, and/or other suitable configurations including those described below with reference to FIGS. 3, 4, and/or 5. The nozzles 106 and 108 are separately and individually controllable. For example, one or more of the parameters discussed above (e.g., flow rate, temperature, angle, chemical composition, etc) can be different for the nozzle 106 than the nozzle 108, as further described below. In an embodiment, the nozzles 106 and/or 108 are moveable along the nozzle positioning arm 112 as they are moveably coupled to the arm 112.

The nozzle 108 may be substantially centered over the wafer 102. The nozzle 106 is disposed along a radius of the wafer 102. Thus, chemical (i.e., chemical 116 and 118) is applied to the wafer 102 at two locations. In other embodiments, any plurality of nozzles introduces chemicals at any plurality of locations on the wafer. In an embodiment, the nozzles 106 and 108 are between approximately 10 mm and approximately 220 mm apart.

The apparatus 100 is operable to provide a different chemical composition from each of the nozzles 106 and 108. Example chemical compositions include those chemicals typically used in semiconductor fabrication such as, de-ionized water (DI), SC1 (de-ionized water (DI), NH₄OH, H₂O2), SC2 (DI, HCl, H₂O₂), ozonated de-ionized water (DIWO₃), SPM (H₂SO₄, H₂O₂), SOM (H₂SO₄, O₃), SPOM, H₃PO₄, dilute hydrofluoric acid (DHF), HF, HF/ethylene glycol (EG), HF/HNO₃, NH₄OH, tetramethylammonium hydroxide (TMAH) or other photosensitive material developer, and/or other suitable chemicals used in semiconductor wafer processing. The apparatus 100 is operable to provide a different chemical concentration from each of the nozzles 106 and 108. The apparatus 100 is operable to provide a chemical at a different temperature from each of the nozzles 106 and 108. For example, the temperature of the dispersed chemical 116 and/or 118 may be between approximately 0 degrees Celsius and approximately 250 degrees Celsius. The apparatus 100 is operable to provide a chemical at a different flow rate from each of the nozzles 106 and 108. For example, the chemical flow rate may be varied between approximately 50 sccm and approximately 5,000 sccm. In an embodiment, the flow rate of the nozzle 108 is greater than the flow rate of nozzle 106. The apparatus 100 is operable to provide a different angle for each of the nozzles 106 and/or 108.

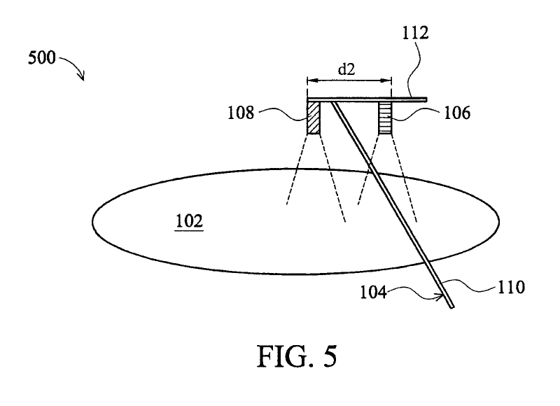

The apparatus 100 is operable to provide a variable physical location of the nozzles 106 and/or 108. In other words, the nozzles 106 and/or 108 are moveably coupled to the nozzle positioning arm 112. For example, in an embodiment, the distance between the nozzle 106 and the nozzle 108 is variable, as described in further detail below with reference to FIGS. 4 and 5.

In an embodiment, the apparatus 100 is configured to perform a polysilicon etching process on the wafer 102. In the exemplary embodiment, the nozzle 108 may be configured to provide (chemical 116) NH₄OH at approximately 50° C. and a flow rate of approximately 700 sccm. The nozzle 106 may be configured to provide (chemical 118) NH₄OH at approximately 60° C. and a flow rate of approximately 500 sccm. In the embodiment, the rotational speed of the wafer 102 may be approximately 800 rpm.

In an embodiment, the apparatus 100 is configured to perform an oxide etching process. In the exemplary embodiment, the nozzle 108 may be configured to provide (chemical 116) dilute HF at approximately 23° C. and a flow rate of approximately 1000 sccm. The nozzle 106 may be configured to provide (chemical 118) dilute HF at approximately 25° C. and a flow rate of approximately 500 sccm. In the embodiment, the rotational speed of the wafer 102 may be approximately 800 rpm.

In an embodiment, the apparatus 100 is configured to perform a TiN wet etching process. In the exemplary embodiment, the nozzle 108 may be configured to provide (chemical 116) SC1 at approximately 50° C. and a flow rate of approximately 1500 sccm. The nozzle 106 may be configured to provide (chemical 118) de-ionized water at approximately 60° C. and a flow rate of approximately 300 sccm. In the embodiment, the rotational speed of the wafer 102 may be approximately 500 rpm.

In an embodiment, the apparatus 100 is configured to perform a TiN wet etching process. In the exemplary embodiment, the nozzle 108 may be configured to provide (chemical 116) SC1 at approximately 50° C. and a flow rate of approximately 1500 sccm. The nozzle 106 may be configured to provide (chemical 118) de-ionized water at approximately 60° C. and a flow rate of approximately 300 sccm. In the embodiment, the arm device 104 may scan from center to edge of the wafer 102. For example, the scan may move the nozzles approximately 100 mm across the radius of the wafer 102 (e.g., towards the edge and back towards the center). The scan function is discussed in further detail below with reference to FIG. 3. In the embodiment, the wafer may be stationary during some or all of the dispersion of chemical.

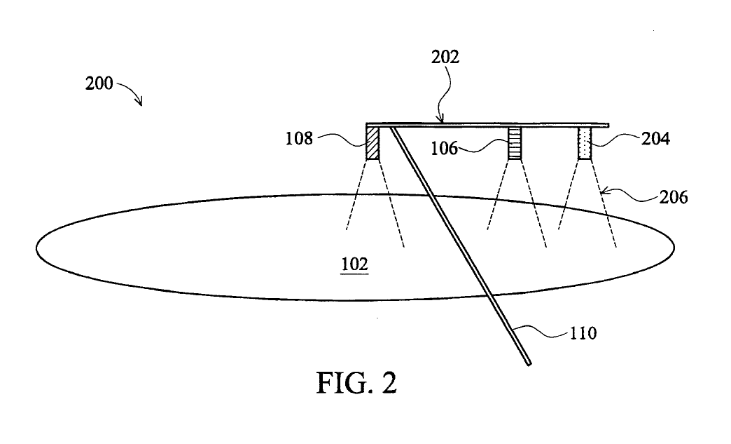

Referring now to FIG. 2, illustrated a chemical dispersion apparatus 200. The chemical dispersion apparatus 200 may be substantially similar to the chemical dispersion apparatus 100, described above with reference to FIGS. 1a and 1b. The chemical dispersion apparatus 200 however has a nozzle positioning arm 202 that includes a third nozzle 204, in addition to the first and second nozzle 106 and 108. The third nozzle 204 disperses a chemical 206. The third nozzle 204 may be substantially similar to the nozzles 106 and/or 108. Like the first and second nozzle 108 and 106, as described above, the third nozzle 204 is separately controllable. For example, the third nozzle 204 can provide a different chemical composition from each of the nozzles 106 and/or 108. The apparatus 200 is operable to provide the same or different chemical concentrations from each of the nozzles 106, 108, and/or 204. The apparatus 200 is operable to provide a chemical at the same or different temperatures from each of the nozzles 106, 108, and/or 204. The apparatus 200 is operable to provide the same or different angles for each of the nozzles 108, 106, and/or 204. The angle of the nozzle may be the angle with respect to the surface of the semiconductor wafer 104. The apparatus 200 is operable to provide the same or different flow rates from each of the nozzles 108, 106, and/or 204. The apparatus 200 is operable to provide a variable physical location of the nozzles 106, 108, and/or 204. For example, in an embodiment, the distance between the nozzle 108, the nozzle 106, and/or nozzle 204 is variable between approximately 10 mm and approximately 220 mm. Though the chemical dispersion apparatus 200 is illustrated as including three nozzles, any plurality of nozzles is possible and within the scope of the present disclosure.

It is noted that as illustrated, the three nozzles 108, 106 and 204 are disposed on the nozzle positioning arm 202, which is substantially linear (e.g., following a radius of the wafer 102). Other embodiments may be possible.

Referring now to FIG. 3, illustrated is a chemical dispersion apparatus 300. The chemical dispersion apparatus 300 may be substantially similar to the chemical dispersion apparatus 100, described above with reference to FIGS. 1a and 1b. Additionally, the chemical dispersion apparatus 300 has an arm device 302 which is operable to provide a scan mode of operation. The arm device 302 includes a main arm 110 which may be substantial similar to as discussed above. The main arm 110 of the arm device 302 is further operable to move the nozzles 108 and/or 106 laterally above the wafer 102, as illustrated by arrows 304. In an embodiment, the main arm 110 is operable to move the nozzle 108 from a position substantially above the center of the wafer 102 to an edge position above the wafer 102. In an embodiment, the main arm 110 is operable to move the nozzle 106 and/or 108 from above one edge of the wafer 102 to above an opposing edge of the wafer 102. In an embodiment, the arm device 302 scans the nozzles from center to edge traversing approximately 100 mm of the wafer 102.

Referring now to FIGS. 4 and 5, illustrated is an embodiment of the chemical dispersion apparatus 100 having a configuration 400 and a configuration 500, respectively. The chemical dispersion apparatus 100 may be substantially similar to as described above with reference to FIG. 1. Configuration 400 of FIG. 4, illustrates the chemical dispersion apparatus 100 having the first nozzle 106 and the second nozzle 108 spaced apart on the nozzle positioning arm 112 a distance d1. Configuration 500 of FIG. 5, illustrates the chemical dispersion apparatus 100 having the first nozzle 106 and the second nozzle 108 spaced apart on the nozzle positioning arm 112 a distance d2. In an embodiment, the distance d2 is less than the distance d1. The distances d1 and d2 may be between approximately 10 mm and approximately 220 mm. The first nozzle 106 and the second nozzle 108 can be repositioned on the nozzle positioning arm 112. In an embodiment, the first nozzle 106 and the second nozzle 108 are moved during the processing of the wafer 102. In an embodiment, first nozzle 106 and the second nozzle 108 are positioned prior to the beginning of the processing of the wafer 102 by the chemical dispersion apparatus 100. In an embodiment, the second nozzle 108 is stationary and the first nozzle 106 is moved. In an embodiment, the movement of the first and/or second nozzles 106 and 108 are determined and/or implemented by a controller operably coupled to the arm 104. The position of the first and/or second nozzles 106 and 108 may be determined based on results of models, experimental data, a diameter of the wafer 102, and/or other suitable characterization techniques.

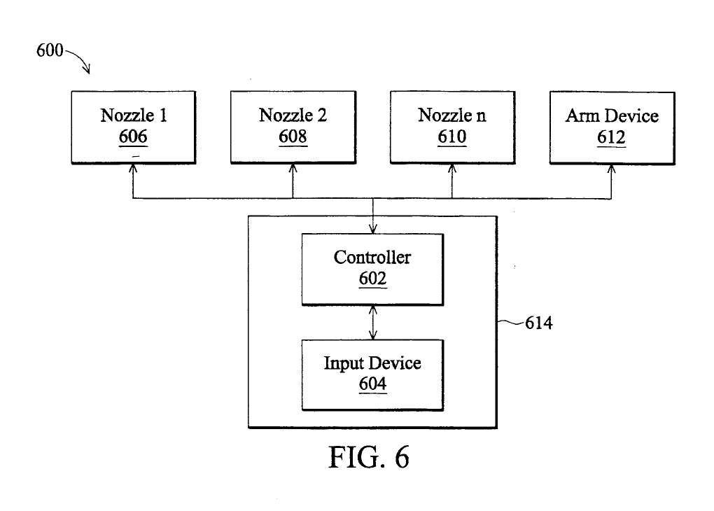

Referring now to FIG. 6, illustrated is a block diagram of a control system 600 of a chemical dispersion apparatus. The system 600 may be included in a chemical dispersion apparatus such as the chemical dispersion apparatus 100, described above with reference to FIGS. 1, 4, 5, the chemical dispersion apparatus 200, described above with reference to FIG. 2, and/or the chemical dispersion apparatus 300, described above with reference to FIG. 3. The control system 600 includes an information handling system 614. The information handing system 614 (e.g., computer) is operable to perform actions including manipulating information (including manipulating information using a model), receiving information, storing information, and transferring information.

The system 600 includes an input device 604. The input device 604 may include a user interface, an interface to other systems found in a semiconductor fabrication facility, such as, interfaces with quality control systems, production control systems, engineering systems, and/or other semiconductor fabrication tools, and/or an interface with a portion of the chemical dispersion apparatus itself (e.g., a storage media). The input device 604 may receive parameters or settings (e.g., recipe parameters) for performing the chemical dispersion. The settings or parameters may include temperature, flow rate, chemical type, chemical concentration, angle of application, time of application, and/or other suitable parameters.

The parameters received by the input device 604 are provided to a controller 602. In an embodiment, the controller 602 determines one or more parameters based on information from the input device 604. The controller 604 may include a microprocessor. The controller 604 is operable to transfer instructions to implement the parameters to portions of the chemical dispersion apparatus, such as, the nozzle 606, nozzle 608, nozzle 610, and arm device 612. The arm device 612 may be substantially similar to the arm 104, 202 and/or 302 described above with reference to FIGS. 1a, 1b, 2, 3, 4, and/or 5, or portions thereof. The nozzles 606, 608, 610 may be substantially similar to the nozzles 106 and/or 108, described above with reference to FIGS. 1a, 1b, 2, 3, 4, and/or 5.

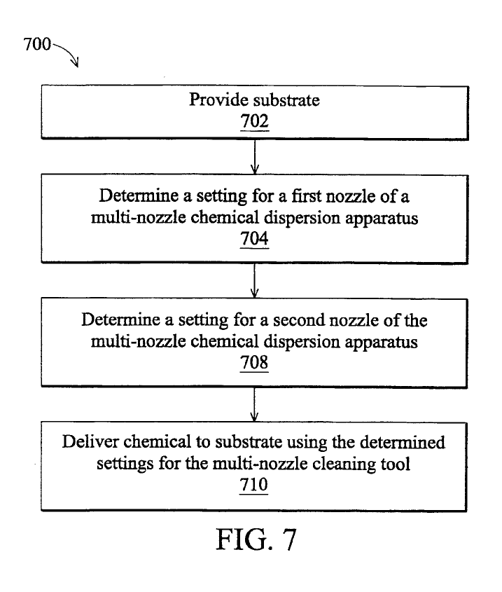

Referring now to FIG. 7, illustrated is a method 700 for dispersing chemicals in a semiconductor device fabrication process using a single-wafer chemical dispersion apparatus. The method 700 may be implemented using the apparatus 100, 200, and/or 300 described above with reference to FIGS. 1a, 1b, 2, 3, 4, and 5. The method 700 may be implemented using the system 600, described above with reference to FIG. 6.

The method 700 begins at block 702 where a substrate is provided. The substrate may be a semiconductor wafer. In an embodiment, the substrate is a 450 mm diameter semiconductor wafer. The substrate provided may be substantially similar to the wafer 102, discussed above with reference to FIGS. 1a and 1b. The substrate may be provided to a stage of a chemical dispersion apparatus, such as, for example, described above with reference to the chuck 114.

The method 700 then proceeds to block 704 where a setting (or parameter, recipe) for a first nozzle of a multi-nozzle chemical dispersion tool is determined for the substrate. The multi-nozzle chemical dispersion tool may be substantially similar to the apparatus 100, 200, and/or 300 described above with reference to FIGS. 1a, 1b, 2, 3, 4, and 5. The setting determined for the first nozzle may include a setting for one or more recipe parameters such as the chemical to be delivered to and dispersed by the first nozzle, the flow rate of the chemical to be delivered to and/or dispersed by the first nozzle, the temperature of the chemical to be delivered to and/or dispersed by the nozzle, the angle of the first nozzle, the physical location of the first nozzle (e.g., on a nozzle positioning arm, such as described above), the concentration of a chemical to be delivered to and/or dispersed by the first nozzle, and/or other recipe parameters.

The method 700 then proceeds to block 706 where a setting for a second nozzle of the multi-nozzle chemical dispersion tool is determined for the substrate. The setting determined for the second nozzle may include a setting for one or more parameters such as the chemical to be delivered to and dispersed by the first nozzle, the flow rate of the chemical to be delivered to and/or dispersed by the second nozzle, the temperature of the chemical to be delivered to and/or dispersed by the nozzle, the angle of the second nozzle, the physical location of the second nozzle (e.g., on a nozzle positioning arm, such as described above), the concentration of a chemical to be delivered to and/or dispersed by the second nozzle, and/or other parameters. In an embodiment, at least one parameter setting differs between the first nozzle, discussed with reference to block 704, and the second nozzle. In an embodiment, the flow rate of the second nozzle is determined to be lower than the flow rate of the first nozzle.

The physical location of the first and second nozzle determined during block 704 and 706 respectively may include determining a distance of separation between the nozzles. Example distances of separation between nozzles include between approximately 10 mm and approximately 250 mm (e.g., for a 450 mm substrate or greater). The determination of the physical location of the first and second nozzle may include a determination to move the location of the first and/or second nozzle during the dispersion of chemical, described below with reference to block 708.

One or more of the settings determined in blocks 704 and 706 may be determined based on the diameter of the substrate provided in block 702, the type of substrate provided in block 702, the devices formed on the block 702, the process performed in block 708 (described below), characterization results associated with the substrate 702, results of models directed to and/or associated with the substrate 702, and/or other considerations.

The method 700 then proceeds to block 708 where chemical is dispersed (or applied) to the substrate according to the determined settings of block 704 and 706. In an embodiment, chemical is delivered by each of the first nozzle and the second nozzle simultaneously. In an embodiment, the chemical dispersed by the first nozzle differs in composition from the chemical delivered by the second nozzle. Example chemical compositions include those chemicals typically used in semiconductor fabrication such as, DI, SC1 (DI, NH₄OH, H₂O2), SC2 (DI, HCl, H₂O₂), ozonated de-ionized water (DIWO₃), SPM (H₂SO₄, H₂O₂), SOM (H₂SO₄, O₃), SPOM, H₃PO₄, dilute hydrofluoric acid (DHF), HF, HF/EG, HF/HNO₃, NH₄OH, tetramethylammonium hydroxide (TMAH) or other photosensitive material developer, and/or other suitable chemicals used in semiconductor wafer processing. In an embodiment, the chemical dispersed by the first nozzle differs in temperature from the chemical dispersed by the second nozzle. Example temperatures of chemicals include those between approximately 0 degrees Celsius and approximately 250 degrees Celsius. In an embodiment, the chemical dispersed by the first nozzle differs in concentration from the chemical dispersed by the second nozzle. In an embodiment, the chemical dispersed by the first nozzle differs in flow rate from the chemical dispersed by the second nozzle. Example flow rates include those between approximately 50 sccm and approximately 5,000 sccm. In an embodiment, the chemical dispersed by the first nozzle at a different angle incident the substrate the chemical dispersed by the second nozzle. In an embodiment, one nozzle may not disperse chemical while the other nozzle is dispersing chemical (e.g., one nozzle may suspend application, delay commencing application, complete application prior to the other nozzle, etc).

In an embodiment, during the block 708, the nozzles may be moved laterally above the substrate such that the positioning of the nozzles above the substrate varies. One such embodiment is discussed above with reference to FIG. 3.

Embodiments of the method 700 may be used to clean the substrate, etch one or more layers or features on the substrate, develop a photosensitive layer formed on the substrate and/or other suitable semiconductor fabrication processes requiring the dispersion of wet chemicals. For example, the method 700 may be used for an oxide etching, SiN etching, polysilicon etching, TiN etching, and/or other suitable etch processes. The following exemplary embodiments of the method 700 are illustrative only and not intended to limit the method 700 to any one semiconductor fabrication process.

In an embodiment, the method 700 includes a polysilicon etching process of the substrate. In block 704, the setting for the first nozzle may be determined to be the provision of NH₄OH at approximately 50° C. and a flow rate of approximately 700 sccm. In block 706, the settings for the second nozzle may be determined to be the provision of NH₄OH at approximately 60° C. and a flow rate of approximately 500 sccm. The rotational speed of the substrate may be approximately 800 rpm during the delivery of the chemical to the substrate.

In an embodiment, the method 700 includes an oxide etching process of the substrate. In block 704, the settings for a first nozzle may be determined to be the provision of dilute HF at approximately 23° C. and a flow rate of approximately 1000 sccm. In block 706, the settings for a second nozzle may be determined to be the provision of dilute HF at approximately 25° C. and a flow rate of approximately 500 sccm. The rotational speed of the substrate may be approximately 800 rpm during the delivery of the chemical to the substrate.

In an embodiment, the method 700 includes a TiN wet etching process of the substrate. In block 704, the settings for a first nozzle may be determined to be the provision of SC1 solution at approximately 50° C. and a flow rate of approximately) 500 sccm. In block 706, the settings for a second nozzle may be determined to be the provision of de-ionized water at approximately 60° C. and a flow rate of approximately 300 sccm. The rotational speed of the substrate may be approximately 500 rpm during the delivery of the chemical to the substrate.

In an embodiment, the method 700 includes a TiN wet etching process of the substrate. In block 704, the settings for a first nozzle may be determined to be the provision of SC1 at approximately 50° C. and a flow rate of approximately 1500 sccm. In block 706, the settings for a second nozzle may be determined to be the provision of de-ionized water at approximately 60° C. and a flow rate of approximately 300 sccm. During the delivery of the determined chemicals in block 708, nozzles may scan from center to edge of the wafer. For example, the scan may move the nozzles approximately 100 mm across the radius of the substrate (e.g., towards the edge and back towards the center) while dispersing the determined chemicals.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

Some embodiments described in the foregoing description provide for apparatus and/or methods that allow for improved etching uniformity across a wafer, flexible positioning of the nozzles which may allow for improved process tuning, tunable chemical flow rates that may improve the process window for the fabrication, increased tuning window for wafer rotational speed, improved chamber particle performance (e.g., scan-free mode), reduced chemical consumption, and/or other features.

Thus, provided in a method of semiconductor fabrication. The method includes providing a substrate and dispensing a first chemical spray onto the substrate using a first nozzle and simultaneously dispensing a second chemical spray using a second nozzle onto the substrate. In an embodiment, the first and second chemical sprays different in at least one parameter (or setting). Example parameters include temperature, composition, concentration, incident angle upon the substrate, and flow rate.

In another embodiment, a method includes providing a semiconductor wafer and a chemical dispersion apparatus. The chemical dispersion apparatus includes a first and second nozzle disposed on an arm. The second nozzle is spaced a distance from the first nozzle. A first chemical is applied (dispersed) to the semiconductor wafer using the first nozzle. A second chemical is applied to the semiconductor wafer using the second nozzle.

Also described is an embodiment of an apparatus. The apparatus includes a wafer chuck, an arm positioned above the wafer chuck, a first nozzle disposed on the arm; and a second nozzle disposed on the arm and spaced a distance from the first nozzle. It is understood that a wafer chuck may be any device operable to hold a single wafer (e.g., semiconductor wafer).

What is claimed is:

1. A method of semiconductor fabrication, the method comprising:
providing a substrate; and
dispensing a first chemical spray onto the substrate using a first nozzle and dispensing a second chemical spray using a second nozzle onto the substrate.

2. The method of claim 1, wherein the first chemical spray includes a different chemical composition than the second chemical spray.

3. The method of claim 1, wherein the first chemical spray has a first temperature during dispensing and the second chemical spray has a second temperature during dispensing, the second temperature being different than the first temperature.

4. The method of claim 1, wherein the first chemical spray is dispensed at a first flow rate and the second chemical spray is dispensed at a second flow rate, the second flow rate being different than the first flow rate.

5. The method of claim 1, wherein the first chemical spray is dispensed at approximately the center of the substrate and wherein the second chemical spray is dispensed at a distance from the center of the substrate.

6. The method of claim 1, further comprising:
determining a location of the first nozzle above the substrate;
determining a desired distance between the first and second nozzle; and
moving at least one of the first nozzle and the second nozzle such that the desired distance is provided between the first and second nozzle.

7. The method of claim 1, further comprising:
etching at least one material formed on the substrate using the first chemical spray and the second chemical spray.

8. The method of claim 1, wherein the first chemical spray is dispensed at a first angle and the second chemical spray is dispensed at a second angle, the second angle being different than the first angle.

9. The method of claim 1, wherein the first nozzle and second nozzle are disposed above the substrate, and wherein the first nozzle is substantially co-planar with the second nozzle and spaced between approximately 10 mm and approximately 220 mm from the second nozzle.

10. A method, the method comprising:
providing a semiconductor wafer;
providing a single-wafer chemical dispersion apparatus, wherein the single-wafer chemical dispersion apparatus includes a first and second nozzle disposed on an arm, wherein the second nozzle is spaced a distance from the first nozzle;
determining a first setting for the first nozzle;
determining a second setting for the second nozzle;
applying a first chemical to the semiconductor wafer using the first nozzle at the first setting; and
applying a second chemical to the semiconductor wafer using the second nozzle at the second setting.

11. The method of claim 10, wherein the first chemical is selected from the group consisting of de-ionized water (DI), SC1 (DI, NH₄OH, H₂O₂), SC2 (DI, HCl, H₂O₂), ozonated de-ionized water (DIO₃), SPM (H₂SO₄, H₂O₂), SOM (H₂SO₄, O₃), SPOM, H₃PO₄, dilute hydrofluoric acid (DHF), HF, HF/EG, HF/HNO₃, NH₄OH, tetramethylammonium hydroxide (TMAH).

12. The method of claim 10, wherein first setting and the second setting include at least one a chemical composition, a chemical concentration, a temperature, an angle of chemical dispersion, and a flow rate.

13. The method of claim 10, further comprising:
moving at least one of the first nozzle and the second nozzle prior to applying the first chemical.

14. The method of claim 10, wherein the first setting is a first flow rate and the second setting is a second flow rate, and wherein the first and second flow rates are different.

15. The method of claim 10, wherein the semiconductor wafer has a diameter of approximately 450 mm or greater.

16. An apparatus, comprising:
a wafer chuck;
an arm device positioned above the wafer chuck;
a first nozzle disposed on the arm device;
a second nozzle disposed on the arm device and spaced a distance from the first nozzle; and
a controller operably coupled to the arm device, wherein the controller is operable to separately control the first nozzle and the second nozzle.

17. The apparatus of claim 16, wherein the controller is operable to move at least one of the first nozzle and the second nozzle.

18. The apparatus of claim 16, further comprising:
a third nozzle disposed on the arm device and spaced a distance from the first and second nozzle.

19. The apparatus of claim 16, wherein the first and second nozzles are moveably coupled to the arm device.

20. The apparatus of claim 16, wherein the second nozzle is spaced a distance of between approximately 10 mm and approximately 220 mm from the first nozzle.
